(19) United States
(12) Patent Application Publication
(10) Pub. No.: US 2006/0181192 A1
(43) Pub. Date: Aug. 17, 2006

(54) White LEDs with tailorable color temperature

(75) Inventors: Emil Vergilov Radkov, Euclid, OH (US); James Reginelli, North Royalton, OH (US); Anant Achyut Setlur, Niskayuna, NY (US)

Correspondence Address: Scott A. McCollister, Esq.;Fay, Sharpe, Fagan, Minnich & McKee, LLP, Seventh Floor, 1100 Superior Avenue, Cleveland, OH, 44114-2579, US

(73) Assignee: GELcore

(21) Appl. No.: 11/400,998

(22) Filed: Apr. 10, 2006

Related U.S. Application Data
(63) Continuation-in-part of application No. 10/909,564, filed on Aug. 2, 2004.

(51) Int. Cl. H01L 33/00; H01J 1/62

(52) U.S. Cl. 313/486

(57) ABSTRACT

A method for the manufacturing of white LEDs is proposed, which can achieve a tunable CCT through the use of at least two phosphor materials, each composition including at least one individual phosphor compound. The method allows optimization of the devices for any desired CCT and approximation of the color coordinates of the black body (Planckian) locus.

This application is a continuation-in-part and claims the benefit of U.S. patent application Ser. No. 10/909,564, filed on Aug. 2, 2004.

### BACKGROUND OF THE INVENTION

The present exemplary embodiments relate to phosphors for the conversion of radiation emitted by a light source. They find particular application in conjunction with converting LED-generated ultraviolet (UV), violet or blue radiation into white light for general illumination purposes. It should be appreciated, however, that the invention is also applicable to the conversion of radiation from UV, violet and/or blue lasers as well as other light sources to white light.

Light emitting diodes (LEDs) are semiconductor light emitters often used as a replacement for other light sources, such as incandescent lamps. They are particularly useful as display lights, warning lights and indicating lights or in other applications where colored light is desired. The color of light produced by an LED is dependent on the type of semiconductor material used in its manufacture.

Colored semiconductor light emitting devices, including light emitting diodes and lasers (both are generally referred to herein as LEDs), have been produced from Group III-V alloys such as gallium nitride (GaN). To form the LEDs, layers of the alloys are typically deposited epitaxially on a substrate, such as silicon carbide or sapphire, and may be doped with a variety of n and p type dopants to improve properties, such as light emission efficiency. With reference to the GaN-based LEDs, light is generally emitted in the UV and/or blue range of the electromagnetic spectrum. Until quite recently, LEDs have not been suitable for lighting uses where a bright white light is needed, due to the inherent color of the light produced by the LED.

Recently, techniques have been developed for converting the light emitted from LEDs to useful light for illumination purposes. In one technique, the LED is coated or covered with a phosphor layer. A phosphor is a luminescent material that absorbs radiation energy in a portion of the electromagnetic spectrum and emits energy in another portion of the electromagnetic spectrum. Phosphors of one important class are crystalline inorganic compounds of very high chemical purity and of controlled composition to which small quantities of other elements (called “activators”) have been added to convert them into efficient fluorescent materials. With the right combination of activators and host inorganic compounds, the color of the emission can be controlled. Most useful and well-known phosphors emit radiation in the visible portion of the electromagnetic spectrum in response to excitation by electromagnetic radiation outside the visible range.

By interposing a phosphor excited by the radiation generated by the LED, light of a different wavelength, e.g., in the visible range of the spectrum, may be generated. Colored LEDs are often used in toys, indicator lights and other devices. Manufacturers are continuously looking for new colored phosphors for use in such LEDs to produce custom colors and higher luminosity.

In addition to colored LEDs, a combination of LED generated light and phosphor generated light may be used to produce white light. The most popular white LEDs are based on blue emitting GaInN chips. The blue emitting chips are coated with a phosphor that converts some of the blue radiation to a complementary color, e.g. a yellow-green emission. The total of the light from the phosphor and the LED chip provides a color point with corresponding color coordinates (e.g. x and y on the 1931 CIE chromaticity diagram) and correlated color temperature (CCT) and vertical distance from the blackbody locus (dbb). Any given set of a CCT and a dbb value (wherein the latter can be positive, negative or zero) corresponds to a single set of an x and a y value, and such sets can be used interchangeably. However, CCT and dbb are defined only in the vicinity of the blackbody (a.k.a. Planckian) locus, whereas x and y cover the entire color space. In white lamps of any CCT, the color point preferably lies substantially on the Planckian locus, and the absolute dbb value is preferably less than 0.010, more preferably less than 0.005, on either side of the Planckian locus in the 1931 CIE diagram.

The spectral power distribution of a white light source provides a color rendering capability, measured by the color rendering index (CRI). The CRI is commonly defined as a mean value for 8 standard color samples (R₁₋₈), usually referred to as the General Color Rendering Index and abbreviated as Rₐ, although 14 standard color samples are specified internationally and one can calculate a broader CRI (R₁₋₁₄) as their mean value. In particular, the R₉ value, measuring the color rendering for the strong red, is very important for a range of applications, especially of medical nature. As used herein, “CRI” is used to refer to any of the above general, mean, or special values unless otherwise specified.

Known white light emitting devices comprise a blue light-emitting LED having a peak emission wavelength in the near blue range (from about 440 nm to about 480 nm) combined with a yellow light-emitting phosphor, such as cerium doped yttrium aluminum garnet (“YAG:Ce”) or a cerium doped terbium aluminum garnet (“TAG:Ce”). The phosphor absorbs a portion of the radiation emitted from the LED and converts the absorbed radiation to a yellow light. The remainder of the blue light emitted by the LED is transmitted through the phosphor and is mixed with the yellow light emitted by the phosphor. A viewer perceives the mixture of blue and yellow light as a white light.

Keeping correlated color temperature (“CCT”) in a specified range is a requirement for white LEDs. This is relatively straightforward for single phosphor lighting devices, but becomes complicated for phosphor blends, especially those using more than two phosphors. Up until now, individual phosphors or phosphor blends in LEDs have been able to only achieve a single CCT with UV chips. Making LED based lighting devices with a given CCT value required a different formulation for each CCT desired on a case by case basis.

So far, it has been very difficult to fine-tune the CCT of a phosphor-converted white light LED. As detailed above, previously proposed methods of white LED manufacturing use either a single phosphor composition, or a layered structure of different colored phosphors. However, the lamp to lamp color variation will be highly objectionable to customers when using layered phosphors if the light emitted by any of the individual layers is not at least substantially white.

With reference to FIG. 1, a conventional phosphor conversion light emitting device 10 as shown. The light emitting device 10 comprises a semiconductor UV or blue radiation source, such as a light emitting diode (LED) chip or die 12 and leads 16, 18 electrically attached to the LED chip. The leads may comprise thin wires supported by a thicker lead frame(s) 14 or the leads may comprise self supported electrodes and the lead frame may be omitted. The leads 16, 18 provide current to the LED chip 12 and thus cause the LED chip 12 to emit radiation. The chip 12 is covered by a phosphor containing layer 20. The phosphor material utilized in the layer 20 can vary, depending upon the desired color of secondary light that will be generated by the layer 20. The chip 12 and the phosphor containing layer 20 are encapsulated by an encapsulant 22.

In operation, electrical power is supplied to the die 12 to activate it. When activated, the chip 12 emits the primary light away from its top surface. The emitted primary light is absorbed by the phosphor containing layer 20. The phosphor layer 20 then emits a secondary light, i.e., converted light having a longer peak wavelength, in response to absorption of the primary light. The secondary light is emitted randomly in various directions by the phosphor in the layer 20. Some of the secondary light is emitted away from the die 12, propagating through the encapsulant 22 and exiting the device 10 as output light. The encapsulant 22 directs the output light in a general direction indicated by arrow 24.

Both the single phosphor approach and the layered structure of different colored phosphors approach provide a given CCT value which is fixed, either by the chemical composition and/or the relative amounts of each phosphor in the phosphor layers, and cannot be changed further without changing the specific phosphors or redesigning the phosphor blend.

It would therefore be desirable to develop new LED based solutions that allow tuning the CCT without affecting or changing the chemical composition of the phosphor blend(s). This affords a set of 2 basic phosphor blends to be used for the manufacturing of white LEDs with different color points that lie substantially along the black body locus. The present invention provides new and improved phosphor layering methods, blends and method of formation, which overcome the above-referenced problems and others.

### SUMMARY OF THE INVENTION

In a first aspect, there is provided a lighting apparatus for emitting white light including a semiconductor light source emitting radiation with a peak emission at from about 250 nm to about 500 nm; a first phosphor material; and a second phosphor material; wherein the first and second phosphor materials have emissions with different x, y color coordinates when subjected to the same source excitation radiation, with the emissions from the first and second phosphor materials lying substantially on the black body locus, taken either alone or with residual light bleed from the semiconductor light source.

In a second aspect, there is provided a method for making a lighting apparatus for emitting white light wherein the CCT value of the apparatus can be tuned, the method including the steps of providing a semiconductor light source emitting radiation having a peak emission at from about 250 to 500 nm; providing first and second phosphor materials radiationally coupled to the light source; wherein the first and second phosphor materials have emissions with different x, y color coordinates when subjected to the same source excitation radiation, with the color coordinates of the emissions from the first and second phosphor materials lying substantially on the black body locus, taken either alone or with residual light bleed from the semiconductor light source, whereby the CCT value of the apparatus can be tuned by varying the relative amounts of each of the first and second phosphor materials present in the apparatus.

In a third aspect, there is provided a white light illumination system comprising a radiation source and first and second phosphor materials, wherein an emission spectrum of the first phosphor material represents a first point on a CIE chromaticity diagram; an emission spectrum of the second phosphor material represents a second point on the CIE chromaticity diagram; the emissions from the first and second phosphor materials lie substantially on the black body locus, taken either alone or with residual light bleed from the radiation source; a first line connecting the first point and the second point lies substantially on the black body locus; and radiation emitted by the system lies substantially on the black body locus.

### BRIEF DESCRIPTION OF THE DRAWINGS

FIG. 1 is a schematic cross-sectional view of a prior art phosphor converted LED illumination system.

FIG. 2 is a schematic sectional view of an LED device in accord with a first embodiment.

FIG. 3 is a schematic sectional view of an LED device in accord with a second embodiment.

FIG. 4 is a schematic sectional view of an LED device in accord with a third embodiment.

FIG. 5 is a graphical representation for the color points achievable in one example relative to the Planckian locus in the 1931 x, y chromaticity diagram.

FIGS. 6a to 6c are the simulated emission spectra for a two phosphor material lighting device as a function of the relative amounts of each phosphor material in accordance with the same example.

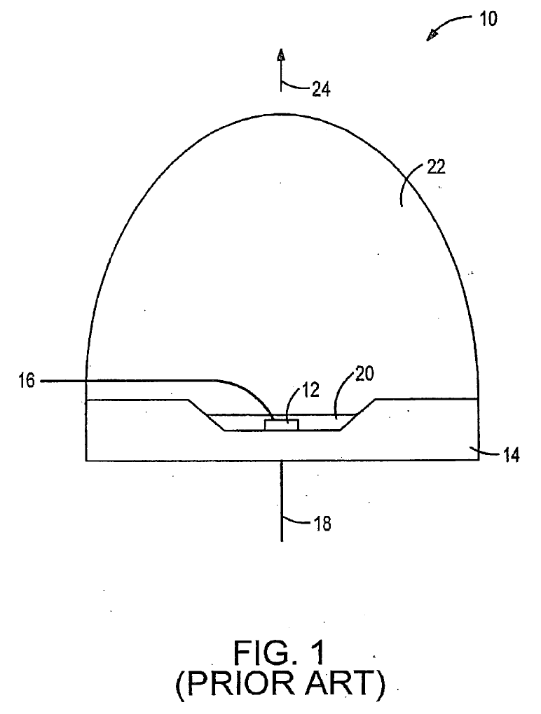

### DETAILED DESCRIPTION OF THE PREFERRED EMBODIMENTS

Novel phosphor lay-down strategies are presented herein as well as their use in LED and other light sources. The color of the generated visible light is dependent on the particular components of the phosphor material. The phosphor material may include only a single phosphor composition or two or more phosphors of basic color, for example a particular mix with one or more of a yellow, red and blue phosphor to emit a white light. As used herein, the terms “phosphor” and “phosphor material” may be used to denote both a single phosphor composition as well as a blend of two or more phosphor compositions.

It was determined that a white light LED lamp that has tunable CCT would be useful. Therefore, in one embodiment, a luminescent material phosphor coated LED chip having at least two distinct phosphor materials with different color coordinates (e.g. on the 1931 CIE chromaticity diagram) is disclosed for providing white light. The phosphor or blend of phosphors in the materials convert radiation at a specified wavelength, for example radiation having a peak from about 250 to 500 nm as emitted by a near UV or visible LED, into a different wavelength visible light.

In one preferred embodiment, each phosphor material (either alone or together with residual bleed from the semiconductor light source) has an emission color point substantially on the black body locus of the 1931 CIE chromaticity diagram. By “substantially”, it is meant that the emission color point of each of the phosphor materials, either alone or together with residual bleed from the LED chip, is less than 0.10 units in the vertical direction from the blackbody (or Planckian) locus in the 1931 x, y chromaticity diagram. In a preferred embodiment, the color point of each phosphor is within 0.010, and more preferably, within 0.005 units of the blackbody locus. Thus, each phosphor material emits substantially white light when excited by the LED, either alone or together with residual bleed from the LED chip. The phosphor materials provide different CCT values, lying along the blackbody locus at different points, more preferably within 0.005 units above the blackbody locus. In another preferred embodiment, the two phosphor materials have CCT values that differ by at least 3500 K.

As described below with reference to the Figures, the phosphor materials may be deposited as distinct layers over the LED chip. However, other arrangements for the phosphor materials are also contemplated, such as an intimate dispersion of the two materials in an encapsulant, or a checkered or segmented pattern. The visible light provided by the phosphor materials (and LED chip if emitting visible light) comprises a bright white light with high intensity and brightness. In one embodiment, the manufacturing of white LEDs using this method would involve creating a minimum of two layers containing phosphor materials A and B, correspondingly. This could be done, e.g., either on a flat substrate (e.g. panels), a curved substrate (e.g. caps) or directly on the LED chip. Still another potential embodiment is where one white light phosphor material is coated directly onto a chip while another white light phosphor material is remotely coated away from the chip.

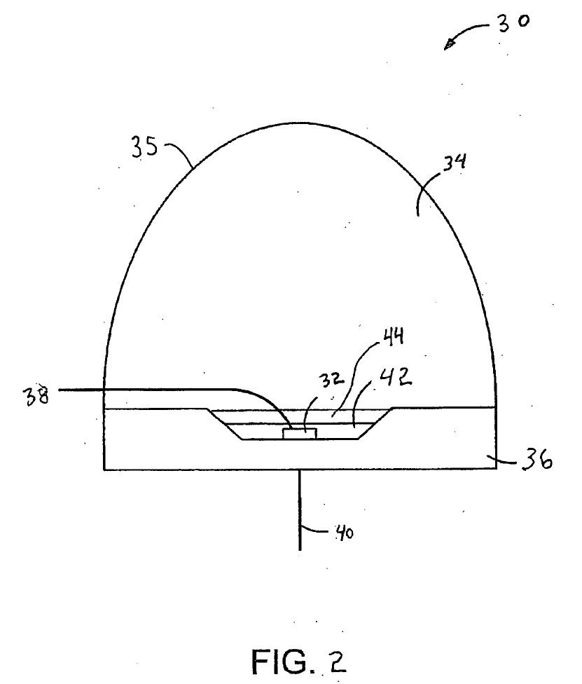

Referring now to FIG. 2, a light-emitting device 30 according to one embodiment of the present invention is shown, including a radiation-emitting semiconductor body (such as an LED chip) 32.

The LED chip 32 may be encapsulated within a shell 35, which encloses the LED chip and an encapsulant material 34. The shell 35 may be, for example, glass or plastic. Preferably, the LED chip 32 is substantially centered in the encapsulant 34. The encapsulant 34 is preferably an epoxy, silicone, plastic, low temperature glass, polymer, thermoplastic, thermoset material, resin or other type of LED encapsulating material as is known in the art. Optionally, the encapsulant 34 is a spin-on glass or some other high index of refraction material. Preferably, the encapsulant material is an epoxy and/or a polymer material, such as silicone or silicone copolymer or blend.

Both the shell 35 and the encapsulant 34 are preferably transparent or substantially optically transmissive with respect to the wavelength of light produced by the LED chip 32 and any phosphor material present (described below). In an alternate embodiment, the lamp 30 may only comprise an encapsulant material without an outer shell. The LED chip 32 may be supported, for example, by the lead frame, by the self supporting electrodes, the bottom of the shell, or by a pedestal (not shown) mounted to the shell or to the lead frame.

As with a conventional LED light emitting device, the semiconductor body 32 may be located within reflector cup lead frame 36 and powered via conductive leads 38 and 40. The cup may be made from or coated with a reflective material, such as alumina, titania, or other dielectric powder known in the art. A preferred reflective material is Al₂O₃. A first phosphor material layer 42 comprised of one or more phosphor compositions and embedded in a matrix of, for example, silicone or other suitable material, is radiationally coupled to the LED chip. Radiationally coupled means that the elements are associated with each other so radiation from one is transmitted to the other. The first layer 42 is positioned between the LED chip and a second phosphor material layer 44, also containing one or more phosphor compositions. In the present description, although reference may be made to a single phosphor composition in each layer, it should be appreciated that both the first and second phosphor materials may contain two or more different phosphor compositions.

Further, although reference is made to two separate phosphor material layers distinct from the encapsulant 34, the exact position of the phosphor materials may be modified, such as embedded in the encapsulant or coated on the lens element. In such a case, the two phosphor materials may be present in a single layer wherein the relative amounts of each may still be adjusted. Thus, although presented in such a way for purposes of explanation, the two phosphor materials may not necessarily form distinct layers or regions. The phosphor materials (in the form of a powder) may be interspersed within a single region or layer of the encapsulant material to form different interspersed or adjacent patterns or arrangements (such as a checkerboard type arrangement) or may even be dispersed throughout the entire volume of the encapsulant material. In fact, the invention does not envision any limitation with respect to the particular location of phosphor materials.

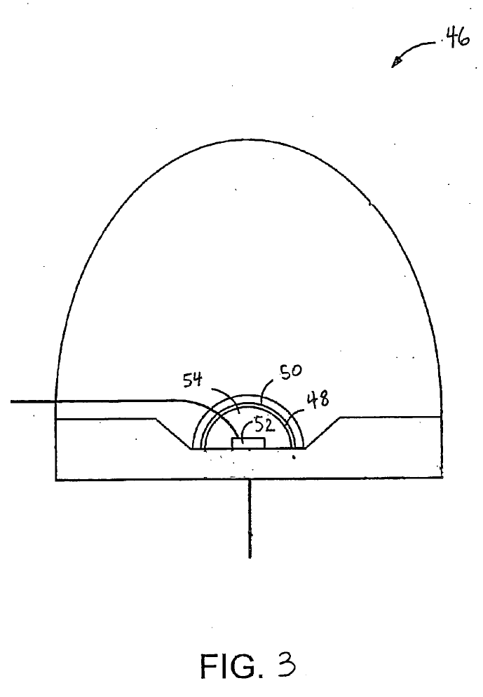

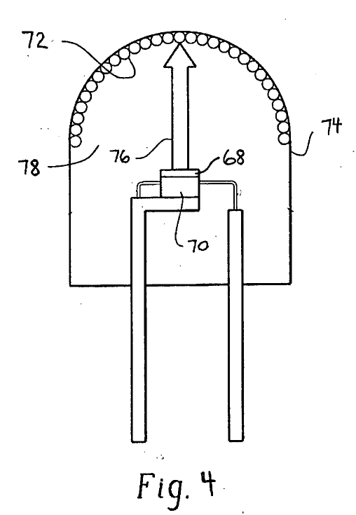

Typically, in a preferred embodiment, regardless of where or how the phosphor materials are positioned in the device, a majority of the first phosphor material particles are preferably positioned closer to the LED chip, or otherwise designed to receive incident light from the LED chip prior to the second phosphor composition particles. Thus, for example, with reference to FIG. 3, a light emitting device 46 is shown in which first and second phosphor material layers 48, 50 are positioned as hemispheres a specified distance away from the LED chip 52 leaving a gap 54. In a third embodiment, as shown in FIG. 4, a light emitting device is shown in which a first phosphor material layer 68 is positioned on an LED chip 70, while a second phosphor material layer 72 is positioned on an outer surface 74 of the LED device. Radiation 76 emitted from the LED chip is absorbed and reemitted by both phosphor material layers while passing through an encapsulant 78. These are merely representative embodiments and should not be considered limiting. In addition, of course, the structures of FIGS. 2-4 may be combined and the phosphor materials may be located in any two or all three locations or in any other suitable location, such as separately from the shell or integrated into the LED.

The lamp may include any semiconductor visible or UV light source that is capable of producing an emission from the phosphor materials when its emitted radiation is directed onto the phosphor materials. The preferred peak emission of the LED chip in the present invention will depend on the identity of the phosphor materials in the disclosed embodiments and may range from, e.g., 250-500 nm. In one preferred embodiment, however, the emission of the LED will be in the near UV to deep blue region and have a peak wavelength in the range from about 360 to about 430 nm. Typically then, the semiconductor light source comprises an LED doped with various impurities. Thus, the LED may comprise a semiconductor diode based on any suitable III-V, II-VI or IV-IV semiconductor layers and having a peak emission wavelength of about 250 to 500 nm.

Preferably, the LED chip may contain at least one semiconductor layer comprising GaN, ZnSe or SiC. For example, the LED chip may comprise a nitride compound semiconductor represented by the formula InᵢGaⱼAlₖN (where 0≦i; 0≦:j; 0≦k and i+j+k=1) having a peak emission wavelength greater than about 250 nm and less than about 500 nm. Such LED semiconductors are known in the art. The radiation source is described herein as an LED for convenience. However, as used herein, the term is meant to encompass all semiconductor radiation sources including, e.g., semiconductor laser diodes, etc.

In addition, although the general discussion of the exemplary structures of the invention discussed herein are directed toward inorganic LED based light sources, it should be understood that the LED chip may be replaced by an organic light emissive structure or other radiation source unless otherwise noted and that any reference to LED chip or semiconductor is merely representative of any appropriate radiation source.

The phosphor material layers in the above embodiments are deposited by any appropriate method. For example, a water based suspension of the phosphor(s) can be formed, and applied as a phosphor layer to the LED surface. In one such method, a silicone slurry in which the phosphor particles are randomly suspended is placed around the LED. If the phosphor is to be interspersed within the encapsulant material, then a phosphor powder may be added to a polymer precursor, loaded around the LED chip, and then the polymer precursor may be cured to solidify the polymer material. These methods are merely exemplary of possible positions of the phosphor layers and LED chip. Thus, the phosphor layers may be coated over or directly on the light emitting surface of the LED chip by coating and drying the phosphor suspension over the LED chip. When present, both the shell and the encapsulant should preferably be substantially transparent to allow radiation from the phosphor layers and, in certain embodiments, the LED chip, to be transmitted therethrough. Although not intended to be limiting, in one embodiment, the median particle size of the phosphor particles in the phosphor materials may be from about 1 to about 10 microns.

In any of the above structures, the lamp 10 may also include a plurality of scattering particles (not shown), which are embedded in the encapsulant material. The scattering particles may comprise, for example, Al₂O₃ particles such as alumina powder or TiO₂ particles. The scattering particles effectively scatter the coherent light emitted from the LED chip, preferably with a negligible amount of absorption.

While the present embodiment shows two phosphor material layers, the invention is not limited to such and embodiments are contemplated containing three or more phosphor materials. Advantageously, a semiconductor material in accord with this invention can be manufactured using conventional production lines.

In one embodiment, the phosphor material layers, when excited by radiation from the LED, have an emission lying substantially on the blackbody locus, but possessing different color coordinates (for example x and y coordinates on the 1931 CIE chromaticity digram), with each material comprising at least 1 individual phosphor composition. Thus, each phosphor material has a substantially white light emission but having a different CCT value with the LED chip to be used (preferably but not necessarily in the violet range, e.g. 405 nm peak emission). As discussed above, in one embodiment, the two phosphor materials have CCT values that differ by at least 3500 K.

For example, the phosphor material A may produce light having a color temperature T_{A} in the range 2000-4000K (corresponding to warm white light having enhanced red and yellow components), while the phosphor material B may produce light having a color temperature TB in the range 4000-10000K (corresponding to cool white light having enhanced green and blue components).

The number of phosphor compositions per material can be anywhere from 1 (such as the phosphors disclosed in U.S. Pat. No. 6,522,065) to 2, 3 or more (such as the phosphor blends disclosed in U.S. Pat. No. 6,685,852), the disclosures of which are incorporated herein in. their entirety.

By varying the amount of the two materials relative to each other in the lighting device, this allows one to alter the CCT of the device. That is, the two phosphor materials, having different color points, can be used to produce a lighting device having a CCT value at any point between the individual CCT values of the individual phosphor materials. The larger the difference between the CCT values of the individual phosphor materials, the larger the range of CCT values that the final device can have.

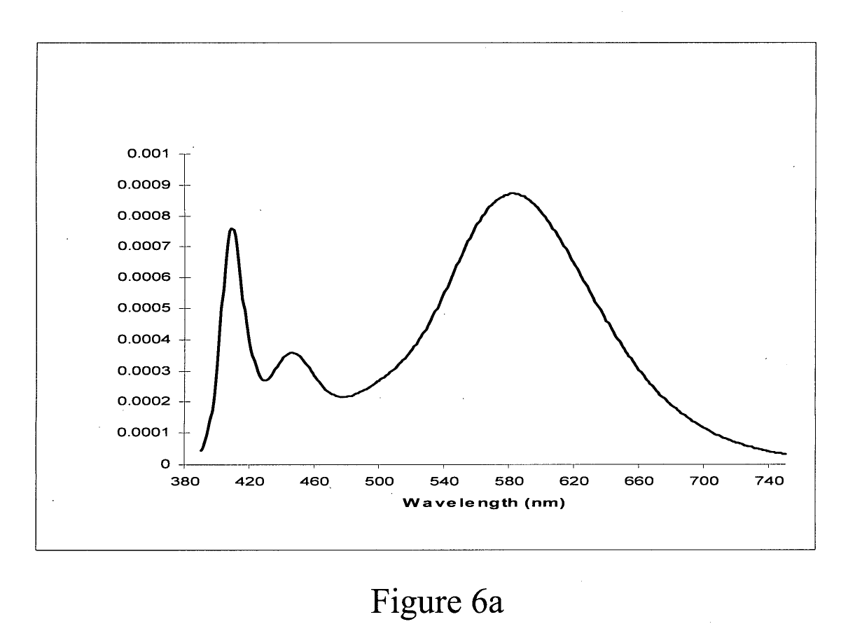

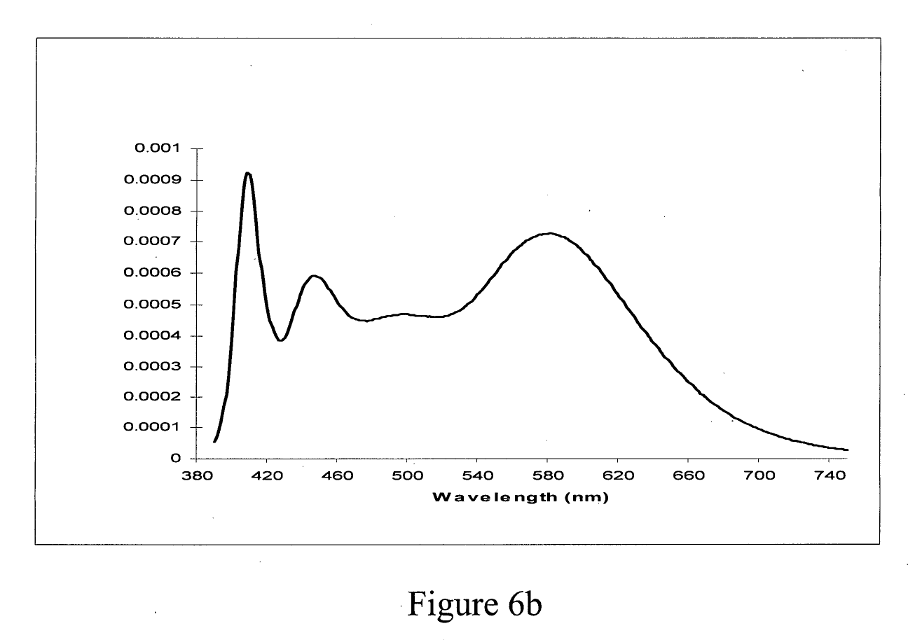

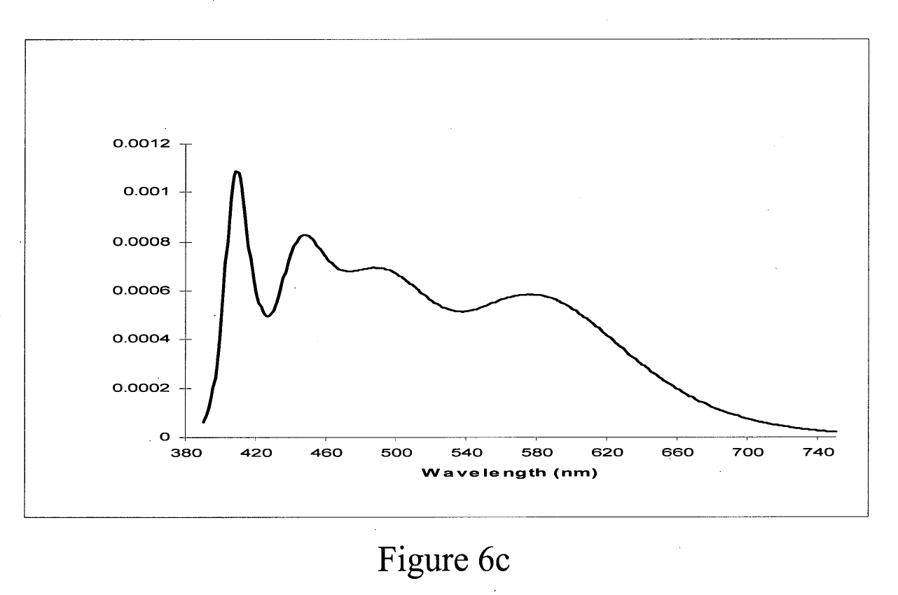

In addition, the dbb of the devices is preferably maintained to within 0.010 units, more preferably to within 0.005 units on either side of the Planckian locus. For reference, FIG. 6 is a graphical representation showing the color points (x,y coordinates) of the spectra relative to the Planckian locus in the 1931 x, y chromaticity diagram. The diagram also shows the variation in color temperature as one moves along the Planckian locus.

Because of the curvature of the Planckian locus as seen in FIG. 6, if both starting phosphor materials either alone or together with residual bleed from the LED chip, provide color points with dbb close to 0, their mixtures may have substantially larger dbb values, as shown in Tables 1 and 3. Even though these absolute values may stay within 0.010 units, it is more preferable to maintain them within 0.005 units from the Planckian locus. This can be achieved, for example, by choosing both starting color points to have slightly positive dbb values, e.g. near 0.005, rather than 0. Then their mixing can maintain the absolute dbb values to within 0.005 throughout the CCT range of mixing due to the curvature of the Planckian locus, as shown in Tables 2 and 4.

Thus, by selecting one phosphor that produces lower color temperature CCT_{A} and another phosphor that produces higher color temperature CCT_{B}, and by selecting their relative contributions appropriately, substantially any correlated color temperature between the lower color temperature CCT_{A} and the higher color temperature CCT_{B} can be achieved, all the while maintaining the dbb within 0.010, more preferably within 0.005 units in absolute value.

The relative contributions are suitably chosen, for example, by selecting thicknesses d_{A}, d_{B} of two phosphor material layers A, B that provide the desired blended color temperature, such thicknesses being suitably selected by experimentation or computer modeling. Advantageously, this enables the manufacturer to produce lighting sources with a color temperature selectable anywhere within the range [CCT_{A}, CCT_{B}] by suitable selection of phosphor deposition time and/or rate parameters for the phosphor materials A, B to provide desired phosphor layer thicknesses d_{A}, d_{B}.

Thus, by varying the amounts of each material in the LED device, one can alter the final CCT of the device in a continuous fashion, while maintaining a consistent white output light on or near the blackbody locus.

In this way, the method disclosed herein allows one to tune the CCT of a lighting device without changing or affecting the chemical makeup of the phosphor compositions used therein or formulating new phosphor blends. This affords a set of at least two basic phosphor materials to be used for the manufacturing of white LEDs with customizable CCT values for specific applications.

As described above, each phosphor material can include one or more individual phosphor compositions. Preferably, the identity of the individual phosphor(s) in each material are selected such that the radiation emitted from each material, when combined with any residual emission from the LED chip, produces a white light.

The specific amounts of the individual phosphor compositions used in the phosphor materials will depend upon the desired color temperature. The relative amounts of each phosphor in the phosphor materials can be described in terms of spectral weight. The spectral weight is the relative amount that each phosphor composition contributes to the overall emission spectrum of the phosphor material. Additionally, part of the LED light may be allowed to bleed through and contribute to the light spectrum of the device if necessary. The amount of LED bleed can be adjusted by changing the optical density of the phosphor layer, as routinely done for industrial blue chip based white LEDs. Alternatively, it may be adjusted by using a suitable filter or a pigment, as described further below.

The spectral weight amounts of all the individual phosphors in each phosphor material should add up to 1 (i.e. 100%) of the emission spectrum of the individual phosphor material. Likewise, the spectral weight amounts of all of the phosphor materials and any residual bleed from the LED source should add up to 100% of the emission spectrum of the light device.

Although not intended to be limiting, particularly preferred phosphors for use in the phosphor materials include garnets activated with at least Ce³⁺(e.g. YAG:Ce, TAG:Ce and their compositional modifications known in the art), and alkaline earth orthosilicates activated with at least Eu²⁺, e.g. (Ba,Sr,Ca)₂SiO₄:Eu²⁺(“BOS”) and its compositional modifications known in the art. Other particularly preferred phosphors are sulfides activated with at least Eu²⁺, e.g. (Sr,Ca)S:Eu²⁺, and M—Si—N nitrides, M—Al—Si—N nitrides, M—Si—O—N oxynitrides or M—Si—Al—O—N sialons activated with at least Eu²⁺(e.g. where M is an alkali or alkaline earth metal) also known in the art.

It is contemplated that various phosphors which are described in this application in which different elements enclosed in parentheses and separated by commas, such as (Sr,Ca)S:Eu²⁺can include any or all of those specified elements in the formulation in any ratio. For example, the phosphor identified above has the same meaning as (SrₐCa₁₋ₐS):Eu²⁺, where a may assume values from 0 to 1, including the values of 0 and 1.

Other phosphors in addition to or in place of the above phosphors may be used. One such suitable phosphor is A₂₋₂ₓNa₁₊ₓEₓD₂V₃O₁₂, wherein A may be Ca, Ba, Sr, or combinations of these; E may be Eu, Dy, Sm, Tm, or Er, or combinations thereof; D may be Mg or Zn, or combinations thereof and x ranges from 0.01 to 0.3. In addition, other suitable phosphors for use in the phosphor materials include:
(Ba,Sr,Ca)₅(PO₄)₃(CI,F,Br,OH):Eu²⁺,Mn²⁺
(Ba,Sr,Ca)BPO₅:Eu²⁺, Mn²⁺
(Sr,Ca)₁₀(PO₄)₆*νB₂O₃:Eu²⁺(wherein 0≦ν≦1)
Sr₂Si₃O₈*2SrCl₂: Eu²⁺
(Ca,Sr,Ba)₃MgSi₂O₈:Eu²⁺,Mn²⁺
BaAl₈O₁₃:Eu²⁺
2SrO*0.84P₂O₅*0.16B₂O₃: Eu²⁺
(Ba,Sr,Ca)MgAl₁₀O₁₇:Eu²⁺,Mn²⁺
(Ba,Sr,Ca)Al₂O₄:Eu²⁺
(Y,Gd,Lu,Sc,La)BO₃:Ce³⁺,Tb³⁺
(Ba,Sr,Ca)₂Si_{1-ξ}O_{4-2ξ}:Eu²⁺(wherein 0≦ξ0.2)
(Ba,Sr,Ca)₂(Mg,Zn)Si₂O₇:Eu²⁺
(Sr,Ca,Ba)(Al,Ga,In)₂S₄:Eu²⁺
(Y,Gd,Tb,La,Sm,Pr,Lu)₃(Sc,Al,Ga)_{5-α}O_{12-3/2α}:Ce³⁺(wherein 0≦α≦0.5)
(Lu,Sc,Y,Tb)₂₋ᵤ₋ᵥCeᵥCa₁₊ᵤLi_{w}Mg_{2-w}P_{w}(Si,Ge)_{3-w}O_{12-u/2} where −0.5≦u≦1; 0≦v≦0.1; and 0≦w≦0.2
(Ca,Sr)₈(Mg,Zn)(SiO₄)₄Cl₂:Eu²⁺,Mn²⁺
Na₂Gd₂B₂O₇:Ce³⁺,Tb³⁺
(Sr,Ca,Ba,Mg,Zn)₂P₂O₇:Eu²⁺,Mn²⁺
(Gd,Y,Lu,La)₂O₃:Eu³⁺,Bi³⁺
(Gd,Y,Lu,La)₂O₂S:Eu³⁺, Bi³⁺
(Gd,Y,Lu,La)VO₄:Eu³⁺,Bi³⁺
(Ca,Sr)S:Eu²⁺,Ce³⁺
ZnS:Cu⁺,CI⁻
ZnS:Cu⁺,Al³⁺
ZnS:Ag⁺,CI⁻
ZnS:Ag⁺,Al³⁺
SrY₂S₄:Eu²⁺
CaLa₂S₄:Ce³⁺
(Ba,Sr,Ca)MgP₂O₇:Eu²⁺,Mn²⁺
(Y,Lu)₂WO₆:Eu³⁺,Mo⁶⁺
(Ba,Sr,Ca)_{β}Si_{γ}N_{μ}:Eu²⁺(wherein 2β+4γ=3μ)
Ca₃(SiO₄)Cl₂:Eu²⁺
(Y,Lu,Gd)_{2-φ},Ca_{φ}Si₄N_{6+φ}C_{1-φ}:Ce³⁺, (wherein 0≦φ≦0.5)
(Lu,Ca,Li,Mg,Y)alpha-SiAlON doped with Eu²⁺and/or Ce³⁺
(Ca,Sr,Ba)SiO₂N₂:Eu²⁺,Ce³⁺
3.5MgO*0.5MgF₂*GeO₂:Mn⁴⁺
Ca_{1-c-f}Ce_{c}Eu_{f}Al_{1+C}Si_{1-C}N₃, (where 0<c≦0.2, 0≦f≦0.2)
Ca₁₋ₕ₋ᵣCeₕEuᵣAl₁₋ₕ(Mg,Zn)ₕSiN₃, (where 0<h≦0.2, 0≦r≦0.2)
Ca₁₋₂ₛ₋ₜCeₛ(Li,Na)ₛEuₜAlSiN₃, (where 0≦s≦0.2, 0≦f≦0.2, s+t>0)
Ca_{1-σ-χ-Φ}Ce_{σ}(Li,Na)_{χ}Eu_{Φ}Al_{1+σ+χ}Si_{1-σ+χ}N₃, (where 0≦σ≦0.2, 0<χ≦0.4, 0≦Φ≦0.2)

For purposes of the present application, it should be understood that when a phosphor has two or more dopant ions (i.e. those ions following the colon in the above compositions), this is to mean that the phosphor has at least one (but not necessarily all) of those dopant ions within the material. That is, as understood by those skilled in the art, this type of notation means that the phosphor can include any or all of those specified ions as dopants in the formulation.

It will be appreciated by a person skilled in the art that other phosphor compositions with sufficiently similar emission spectra may be used instead of any of the preceding suitable examples, even though the chemical formulations of such substitutes may be significantly different from the aforementioned examples.

In one embodiment, the at least two different phosphor materials comprise the same phosphor compositions, albeit in different spectral weights. That is, the materials may comprise the same blend of phosphors in different proportions. Each of the phosphor materials with thus have different color coordinates due to the relative spectral weights of the individual phosphor compositions in the blends.

The ratio of each of the individual phosphor compositions in each of the phosphor materials may vary depending on the characteristics of the desired light output. As discussed above, the white light from each phosphor material preferably lies substantially on the blackbody locus, albeit with different CCT values. As stated, however, the exact identity and amounts of each phosphor compound in the phosphor material can be varied according to the needs of the end user.

It may be desirable to add pigments or filters to the phosphor materials. Thus, the phosphor materials and/or encapsulant may also comprise from 0 up to about 20% by weight (based on the total weight of the phosphors) of a pigment or other UV absorbent material capable of absorbing UV radiation having a wavelength between 250 nm and 500 nm.

Suitable pigments or filters include any of those known in the art that are capable of absorbing radiation generated between 250 nm and 500 nm. Such pigments include, for example, nickel titanate or praseodymium zirconate. The pigment is used in an amount effective to filter 10% to 100% of the radiation generated in the 250 nm to 450 nm range.

By assigning appropriate spectral weights for each phosphor composition, one can create spectral blends for use in each phosphor material to cover the relevant portions of color space, especially for white lamps. Specific examples of this are shown below. For various desired color points, one can determine the identity and appropriate amounts of each phosphor composition to include in the individual materials. Thus, one can customize phosphor blends for use in the materials to produce almost any CCT or color point, with control over the CRI and luminosity based on the amount of each material in the lighting device.

By use of the present embodiments wherein two or more phosphor materials with different color points are used in a lighting device, lamps can be provided having customizable CCT. The preparation of each phosphor material, including the identity and amounts of each phosphor composition present therein, and the evaluation of its contribution to the LED spectrum would be trivial for a person skilled in the art and can be done using established techniques aided by, e.g., the DOE approach such as the preparation of a series of devices with various thicknesses of two phosphor materials.

### EXAMPLES

Light sources using phosphor blends according to the above embodiments may be produced. Two different exemplary prophetic trials are presented. In a first trial, two different phosphor material layers A and B are investigated. These trials were conducted using two triphosphor materials having the same three phosphors with different spectral weight fractions for each phosphor composition in the two materials. The spectral weight amounts of each phosphor in material layers A and B are listed in Table 1. These amounts are determined using single phosphor LEDs each containing LED radiation bleeding through the phosphor coating. The phosphors selected for this trial were Sr₄Al₁₄O₂₅:Eu²⁺(“SAE”), (Ca,Sr)₂SiO₄:Eu²⁺(“BOS”), and (Ca,Sr,Ba)₅(PO₄)₃Cl:Eu²⁺(“SECA”). The CCT of material A under 405 nm excitation is 3500 K and the CCT of material B is 8000 K.

TABLE 1

| Material | SAE | BOS | SECA | Total |
|---|---|---|---|---|
| A | 0.025 | 0.875 | 0.100 | 1.0000 |
| B | 0.226 | 0.548 | 0.226 | 1.0000 |

Table 2 shows a set of simulated spectral models at different levels of spectral contribution from materials A and B (0 to 100% each in 10% increments) under 405 nm LED chip excitation, with added bleed from the chip. Of course, other combinations are also possible, e.g. 75% of material A and 25% of material B, as needed to achieve specific target CCt values.

TABLE 2

| Point # | B | A | x | y | CCT | dbb |
|---|---|---|---|---|---|---|
| 1 | 100% | 0% | 0.406 | 0.392 | 3500 | 0.000 |
| 2 | 90% | 10% | 0.393 | 0.382 | 3705 | −0.003 |
| 3 | 80% | 20% | 0.381 | 0.372 | 3940 | −0.006 |
| 4 | 70% | 30% | 0.370 | 0.363 | 4212 | −0.007 |
| 5 | 60% | 40% | 0.358 | 0.354 | 4527 | −0.008 |
| 6 | 50% | 50% | 0.347 | 0.345 | 4893 | −0.008 |
| 7 | 40% | 60% | 0.336 | 0.337 | 5321 | −0.008 |
| 8 | 30% | 70% | 0.326 | 0.328 | 5825 | −0.006 |
| 9 | 20% | 80% | 0.315 | 0.320 | 6419 | −0.005 |
| 10 | 10% | 90% | 0.305 | 0.312 | 7132 | −0.003 |
| 11 | 0% | 100% | 0.295 | 0.304 | 8000 | 0.000 |

It can be seen from Table 2 that a lighting device having any desired CCT value between 3500 K and 8000 K can be made by varying the relative amounts of each of materials A and B, without the need to alter the composition of A or B. Thus, it can be seen how the present invention allows one to easily tune the CCT of a white light device to any value without the need to reformulate the phosphor blend.

Similarly, a second set of trials using a phosphor blend containing the same phosphors in slightly different amounts was conducted. The composition of the two materials A and B is shown in Table 3. These amountts are determined using single phosphor LEDs each containing LED radiation bleeding through the phosphor coating.

TABLE 3

| Material | SAE | BOS | SECA | Total |
|---|---|---|---|---|
| A | 0.032 | 0.876 | 0.092 | 1.0000 |
| B | 0.239 | 0.542 | 0.220 | 1.0000 |

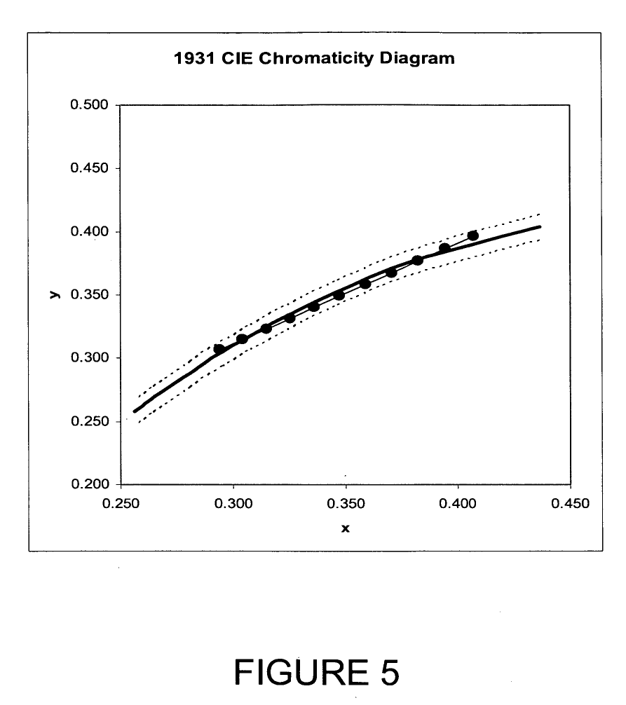

Table 4 shows a set of simulated spectral models at different levels of spectral contribution from materials A and B (0 to 100% each in 10% increments) under 405 nm LED chip excitation, with added bleed from the chip. It can be seen that the dbb value for the resultant combined emission of both phosphor materials A and B is close to zero for each point, and that the resultant light has a color point well within 0.010 units of either side of the Plackian locus, as illustrated in FIG. 5 (thick solid line showing blackbody locus, dashed lines marking 0.01 units distance on both sides, circular dots showing x, y coordinates from Table 4). It can also be seen from FIG. 5 that the entire line connecting the data points lies substantially on the blackbody locus.

TABLE 4

| Point # | B | A | x | y | CCT | dbb |
|---|---|---|---|---|---|---|
| 1 | 100% | 0% | 0.407 | 0.396 | 3500 | 0.004 |
| 2 | 90% | 10% | 0.395 | 0.387 | 3706 | 0.001 |
| 3 | 80% | 20% | 0.382 | 0.377 | 3943 | −0.002 |
| 4 | 70% | 30% | 0.371 | 0.367 | 4215 | −0.003 |
| 5 | 60% | 40% | 0.359 | 0.358 | 4531 | −0.004 |
| 6 | 50% | 50% | 0.347 | 0.349 | 4898 | −0.004 |
| 7 | 40% | 60% | 0.336 | 0.340 | 5325 | −0.004 |
| 8 | 30% | 70% | 0.325 | 0.332 | 5829 | −0.003 |
| 9 | 20% | 80% | 0.315 | 0.323 | 6423 | −0.001 |
| 10 | 10% | 90% | 0.305 | 0.315 | 7135 | 0.001 |
| 11 | 0% | 100% | 0.294 | 0.307 | 8000 | 0.004 |

The simulated emission spectra for LED systems corresponding to points 1, 6, and 11 of Table 4 are shown in FIGS. 6a-6c, respectively.

It should be noted that these examples are exemplary in nature and in no way are meant to be exhaustive or restrictive of the scope of the invention, but are for illustation of the concept of this invention. One skilled in the art will recognize the applicability of the inventive concept to a large number of different embodiments.

The invention has been described with reference to the preferred embodiment. Obviously, modifications and alterations will occur to others upon reading and understanding the preceding, detailed description. It is intended that the invention be construed as including all such modifications and alterations, insofar as they come within the scope of the appended claims or the equivalents thereof.

What is claimed is

1. A lighting apparatus for emitting white light comprising:
a semiconductor light source emitting radiation having a peak emission in the range of from about 250 to 500 nm;
a first phosphor material comprising at least one phosphor composition radiationally coupled to said light source; and
a second phosphor material comprising at least one phosphor composition radiationally coupled to said light source; wherein the first and second phosphor materials have emissions with different x, y color coordinates on the 1931 CIE chromaticity diagram when subjected to the same source excitation radiation, with the emissions from the first and second phosphor materials lying substantially on the black body locus, taken either alone or with residual light bleed from the semiconductor light source.

2. The lighting apparatus of claim 1, further including a pigment, filter or other absorber capable of absorbing radiation generated between 250 nm and 450 nm.

3. The lighting apparatus of claim 1, wherein at least one of said first and second phosphor materials comprises two or more phosphor compositions.

4. The lighting apparatus of claim 3, wherein said first and second phosphor materials comprise the same phosphor compositions in different ratios.

5. The lighting apparatus of claim 1, wherein at least one of said first and second phosphor materials comprises at least one of a garnet activated with at least Ce³⁺, an orthosilicate activated with at least Eu²⁺, a sulfide activated with at least Eu²⁺, and/or a nitride, oxynitride or sialon activated with at least Eu²⁺.

6. The lighting apparatus of claim 1, where said first and second phosphor materials have emissions with color points that lie on or substantially on the black body locus.

7. The lighting apparatus of claim 6, where said color points of said emissions are within 0.01 of the black body locus in the vertical direction on the 1931 CIE chromaticity diagram.

8. The lighting apparatus of claim 1, wherein a CCT value of radiation emitted by said lighting apparatus can be altered by modifying the relative amounts of said first and second phosphor compositions present in said apparatus.

9. The lighting apparatus of claim 8, wherein said radiation has a color point that lies on or substantially on the black body locus.

10. The lighting apparatus of claim 1, wherein said first and second phosphor materials are in the form of discrete layers.

11. The lighting apparatus of claim 1, wherein said emissions from said first and second phosphor materials, either alone or with residual light bleed from the semiconductor light source, have CCT values that differ by at least 3500 K.

12. The lighting apparatus of claim 1, wherein said first and second phosphor materials comprise one or more phosphor compositions selected from the group including: (Ba,Sr,Ca)₅(PO₄)₃(Cl,F,Br,OH):Eu²⁺, Mn²⁺;(Ba,Sr,Ca)BPO₅:Eu²⁺,Mn²⁺; (Sr, Ca)₁₀(PO₄)₆*νB₂O₃:Eu²⁺(wherein 0<ν>1); Sr₂Si₃O₈*2SrCl₂:Eu²⁺; (Ca, Sr, Ba)₃MgSi₂O₈:Eu²⁺, Mn²⁺; BaAl₈O₁₃:Eu²⁺; 2SrO*0.84P₂O₅*0.16B₂O₃: Eu²⁺; (Ba,Sr,Ca)MgAl₁₀O₁₇:Eu²⁺,Mn²⁺; (Ba,Sr,Ca)Al₂O₄:Eu²⁺; (Y,Gd,Lu,Sc,La)BO₃:Ce³⁺,Tb³⁺; ZnS:Cu⁺,Cl⁻; ZnS:Cu⁺,Al³⁺; ZnS:Ag⁺,Cl⁻; ZnS:Ag⁺,Al³⁺; (Ba,Sr,Ca)₂Si_{1-ξ}O_{4-2ξ}:Eu²⁺(wherein 0≦ξ≦0.2); (Ba,Sr,Ca)₂(Mg,Zn)Si₂O₇:Eu²⁺; (Sr,Ca,Ba)(Al,Ga,In)₂S₄:Eu²⁺; (Y,Gd,Tb,La,Sm,Pr,Lu)₃(Al,Ga)_{5-α}O_{12-3/2α}:Ce³⁺(wherein 0≦α≦0.5); (Ca,Sr)₈(Mg,Zn)(SiO₄)₄Cl₂:Eu²⁺, Mn²⁺; Na₂Gd₂B₂O₇:Ce³⁺,Tb³⁺; (Sr,Ca,Ba,Mg,Zn)₂P₂O₇:Eu²⁺,Mn²⁺; (Gd,Y,Lu,La)₂O₃:Eu³⁺,Bi³⁺; (Gd,Y,Lu,La)₂O₂S:Eu³⁺,Bi³⁺; (Gd,Y,Lu,La)VO₄:Eu³⁺,Bi³⁺; (Ca,Sr)S:Eu²⁺,Ce³⁺; SrY₂S₄:Eu²⁺; CaLa₂S₄:Ce³⁺; (Ba,Sr,Ca)MgP₂O₇:Eu²⁺, Mn²⁺; (Y,Lu)₂WO₆:Eu³⁺,Mo⁶⁺; (Ba,Sr,Ca)_{β}Si_{γ}N_{μ}:Eu²⁺(wherein 2β+4γ=3μ); Ca₃(SiO₄)Cl₂:Eu²⁺; (Lu,Sc,Y,Tb)₂₋ᵤ₋ᵥ CeᵥCa₁₋ᵤLi_{w}Mg_{2-w}P_{w}(Si,Ge)_{3-w}O_{12-u/2} (where −0.5≦u≦1, 0≦v≦0.1, and 0≦w≦0.2); (Y,Lu,Gd)2-φ,Ca_{φ},Si₄N_{6+φ}C_{1φ}:Ce³⁺(wherein 0≦φ≦0.5); (Lu,Ca,Li,Mg,Y)alpha-SiAION doped with Eu²⁺and/or Ce³⁺; (Ca,Sr,Ba)SiO₂N₂:Eu²⁺,Ce³⁺; 3.5MgO*0.5MgF₂*GeO₂:Mn⁴⁺; Ca_{1-c-f}Ce_{C}Eu_{f}Al_{1+C}Si_{1-C}N₃, (where 0≦c≦0.2, 0≦f0.2); Ca₁₋ₕ₋ᵣCeₕEuᵣAl₁₋ₕ(Mg,Zn)ₕSiN₃, (where 0≦h≦0.2, 0≦r≦0.2); Ca₁₋₂ₛ₋ₜCeₛ(Li,Na)ₛEuₜAlSiN₃, (where 0≦s≦0.2, 0≦f≦0.2, s+t>0); and Ca_{1-σ-χ-φ}Ce_{σ}(Li,Na)_{χ}Eu_{χ}Al_{1+σ-χ}Si_{1+σ-χ}N₃, (where 0>σ≦0.2, 0≦χ≦0.4, 0≦Φ≦0.2).

13. A method for making a lighting apparatus for emitting white light which can achieve a tunable CCT by varying the amounts of first and second phosphor materials present in said apparatus, the method including the steps of
providing a semiconductor light source emitting radiation having a peak emission at from about 250 to 500 nm;
providing a first phosphor material comprising at least one phosphor composition radiationally coupled to said light source; and
providing a second phosphor material comprising at least one phosphor composition radiationally coupled to said light source; wherein the first and second phosphor materials have emissions with different x, y color coordinates on the 1931 CIE chromaticity diagram when subjected to the same source excitation radiation, with the emissions from the first and second phosphor materials lying substantially on the black body locus, taken either alone or with residual light bleed from the semiconductor light source.

14. The method of claim 13, further comprising providing a pigment, filter or other absorber capable of absorbing radiation generated between 250 nm and 450 nm to absorb radiation emitted from said light source.

15. The method of claim 13, wherein at least one of said first and second phosphor materials comprises two or more phosphor compositions.

16. The method of claim 13, wherein at least one of said first and second phosphor materials comprises at least one of a garnet activated with at least Ce³⁺, an orthosilicate activated with at least Eu²⁺, a sulfide activated with at least Eu²⁺, and/or a nitride, oxynitride or sialon activated with at least Eu²⁺.

17. The method of claim 13, where said first and second phosphor emissions have color points that lie on or substantially on the black body locus.

18. The method of claim 13, where said emissions are within 0.01 from the black body locus in the vertical direction.

19. The method of claim 13, wherein a CCT value of radiation emitted by said lighting apparatus can be altered by modifying the relative amounts of said first and second phosphor compositions present in said apparatus.

20. The method of claim 19, wherein said radiation has a color point that lies on or substantially on the black body locus.

21. The method of claim 13, wherein said first and second phosphor materials are in the form of discrete layers.

22. The method of claim 13, wherein said emissions from said first and second phosphor materials, either alone or with residual light bleed from the semiconductor light source, have CCT values that differ by at least 3500 K.

23. The method of claim 13, wherein said first and second phosphor materials comprise one or more phosphor compositions selected from the group including: (Ba,Sr,Ca)₅(PO₄)₃(Cl,F,Br,OH):Eu²⁺,Mn²⁺; (Ba,Sr,Ca)BPO₅:Eu²⁺,Mn²⁺; (Sr,Ca)₁₀(PO₄)₆*υB₂O₃:Eu²⁺(wherein 0<ν≦1); Sr₂Si₃O₈*2SrCl₂:Eu²⁺; (Ca,Sr,Ba)₃MgSi₂O₈:Eu²⁺,Mn²⁺; BaAI₈O₁₃:Eu²⁺; 2SrO*0.84P₂O₅*0.16B₂O₃:Eu²⁺; (Ba,Sr,Ca)MgAl₁₀O₁₇:Eu²⁺,Mn²⁺; (Ba,Sr,Ca)Al₂O₄:Eu²⁺; (Y,Gd,Lu,Sc,La)BO₃:Ce³⁺,Tb³⁺; ZnS:Cu⁺,Cl⁻; ZnS:Cu⁺,Al³⁺; ZnS:Ag⁺,Cl⁻; ZnS:Ag⁺,Al³⁺; (Ba,Sr,Ca)₂Si_{1-ξ}O_{4-2ξ}:Eu²⁺(wherein 0≦ξ≦0.2); (Ba,Sr,Ca)₂(Mg,Zn)Si₂O₇:Eu²⁺; (Sr,Ca,Ba)(AI,Ga,ln)₂S₄:Eu²⁺; (Y,Gd,Tb,La,Sm,Pr,Lu)₃(Al,Ga)_{5-α},O_{12-3α}:Ce³⁺(wherein 0≦α≦0.5); (Ca,Sr)₈(Mg,Zn)(SiO₄)₄Cl₂:Eu²⁺, Mn²⁺; Na₂Gd₂B₂O₇:Ce³⁺,Tb³⁺; (Sr,Ca, Ba,Mg,Zn)₂P₂O₇:Eu²⁺,Mn²⁺;(Gd,Y,Lu,La)₂O₃:Eu³⁺,Bi³⁺; (Gd,Y,Lu,La)₂O₂S:Eu³⁺, Bi³⁺; (Gd,Y,Lu,La)VO₄:Eu³⁺,Bi³⁺; (Ca,Sr)S:Eu²⁺,Ce³⁺; SrY₂S₄:Eu²⁺; CaLa₂S₄:Ce³⁺; (Ba,Sr,Ca)MgP₂O₇:Eu²⁺,Mn²⁺; (Y,Lu)₂WO₆:Eu³⁺,Mo⁶⁺; (Ba,Sr,Ca)_{β}Si_{γ}N_{μ}:Eu²⁺(wherein 2β+4γ=3μ); Ca₃(SiO₄)CI₂:Eu²⁺; (Lu,Sc,Y,Tb)₂₋ᵤ₋ᵥCeᵥCa₁₊ᵤLi_{w}Mg_{2-w}P_{w}(Si,Ge)_{3-w}O_{12-u/2} (where −0.5≦u≦1, 0≦v<0.1, and o≦w≦0.2); (Y,Lu,Gd)_{2-φ},Ca_{φ}Si₄N_{6+φ},C_{1-φ},:Ce³⁺, (wherein 0≦φ≦0.5); (Lu,Ca,Li,Mg,Y)alpha-SiAION doped with Eu²⁺and/or Ce³⁺; (Ca,Sr,Ba)SiO₂N₂:Eu²⁺,Ce³⁺; 3.5MgO*0.5MgF₂*GeO₂:Mn⁴⁺; Ca_{1-c-f}Ce_{C}Eu_{f}Al_{1+C}Si_{1-c}N₃, (where 0≦c≦0.2, 0≦f≦0.2); Ca₁₋ₕ₋ᵣCeₕEuᵣA1₁₋ₕ(Mg,Zn)ₕSiN₃, (where 0≦h≦0.2, 0≦r≦0.2); Ca₁₋₂ₛ₋ₜCeₛ(Li,Na)ₛEuₜAlSiN₃, (where 0≦s≦0.2, 0≦f≦0.2, s+t>0); and Ca_{1-σ-χ-Φ}Ce_{σ}(Li,Na)_{χ}Eu_{Φ}Al_{1+σ-Φ}Si_{1-+Φ}N₃, (where 0≦σ≦0.2, 0≦χ≦0.4, 0≦Φ≦0.2).

24. A white light illumination system comprising a radiation source and first and second phosphor materials, wherein:
an emission spectrum of the first phosphor material represents a first point on a CIE chromaticity diagram;
an emission spectrum of the second phosphor material represents a second point on the CIE chromaticity diagram;
the emissions from the first and second phosphor materials lie substantially on the black body locus, taken either alone or with residual light bleed from the radiation source;
a first line connecting the first point and the second point lies substantially on the black body locus; and
radiation emitted by the system lies substantially on the black body locus.
